(19) United States
(12) Patent Application Publication
(10) Pub. No.: US 2010/0052190 A1
(43) Pub. Date: Mar. 4, 2010

(54) SEMICONDUCTOR DEVICE

(75) Inventor: Osamu FURUKAWA, Hyogo-ken (JP)

Correspondence Address: PATTERSON & SHERIDAN, L.L.P., 3040 POST OAK BOULEVARD, SUITE 1500, HOUSTON, TX, 77056, US

(73) Assignee: KABUSHIKI KAISHA TOSHIBA, Tokyo (JP)

(21) Appl. No.: 12/500,972

(22) Filed: Jul. 10, 2009

(30) Foreign Application Priority Data
Aug. 27, 2008 (JP) 2008-218743

(51) Int. Cl. H01L 23/28

(52) U.S. Cl. 257/787; 257/E23.116

(57) ABSTRACT

A semiconductor device includes: a base plate; a semiconductor element provided on the base plate; a holder provided on an opposite side of the semiconductor element from the base plate and holding terminals electrically connected to the semiconductor element; a casing surrounding the semiconductor element and opposed to a side surface of the holder; and a sealing resin filled among the base plate, the casing, and the holder. The side surface of the holder is provided with a first protrusion protruding toward the casing. The first protrusion is nearer to the base plate than a major surface of the holder on an opposite side from the base plate. A surface of the first protrusion on an opposite side from the base plate is at least partly buried in the sealing resin.

### CROSS-REFERENCE TO RELATED APPLICATIONS

This application is based upon and claims the benefit of priority from the prior Japanese Patent Application No. 2008-218743, filed on Aug. 27, 2008; the entire contents of which are incorporated herein by reference.

### BACKGROUND OF THE INVENTION

1. Field of the Invention

This invention relates to a resin-sealed semiconductor device.

2. Background Art

In a power semiconductor device, a semiconductor chip is attached onto a base plate and electrically connected to terminals held on a holder provided above the semiconductor chip, and a resin is filled between the base plate and the terminal holder. When using such a semiconductor device, the base plate is fixed to a heat-dissipating fin, for example, which is separately provided. On the other hand, the terminals are fixed to an electrical circuit section, for example, which is separately provided. Hence, a stress is applied between the base plate and the terminal holder.

In conventional semiconductor devices, this stress causes shear delamination at the interface between the holder and the sealing resin, which results in the problem of deteriorated reliability.

JP-A-11-238821 (Kokai) (1999) discloses a technique for a power semiconductor module in which a ceiling plate for resin sealing is engaged with the upper end portion of a resin casing.

### SUMMARY OF THE INVENTION

According to an aspect of the invention, there is provided a semiconductor device including: a base plate; a semiconductor element provided on the base plate; a holder provided on an opposite side of the semiconductor element from the base plate and holding terminals electrically connected to the semiconductor element; a casing surrounding the semiconductor element and opposed to a side surface of the holder; and a sealing resin filled among the base plate, the casing, and the holder, the side surface of the holder being provided with a first protrusion protruding toward the casing, the first protrusion being nearer to the base plate than a major surface of the holder on an opposite side from the base plate, and a surface of the first protrusion on an opposite side from the base plate being at least partly buried in the sealing resin.

### BRIEF DESCRIPTION OF THE DRAWINGS

FIG. 1 is a schematic cross-sectional view illustrating the configuration of a semiconductor device according to a first embodiment of the invention;

FIG. 2 is a schematic cross-sectional view illustrating the configuration of a semiconductor device of a comparative example;

FIG. 3 is a schematic cross-sectional view illustrating the configuration of a semiconductor device according to a second embodiment of the invention;

FIG. 4 is a schematic cross-sectional view illustrating the configuration of a semiconductor device according to a third embodiment of the invention;

FIG. 5 is a schematic cross-sectional view illustrating the configuration of a semiconductor device according to a fourth embodiment of the invention;

FIG. 6 is a schematic cross-sectional view illustrating the configuration of a semiconductor device according to a fifth embodiment of the invention;

FIGS. 7A to 7D are schematic plan views illustrating configurations of the semiconductor device according to the embodiments of the invention; and

FIGS. 8A to 8C are schematic plan views illustrating other configurations of the semiconductor device according to the embodiments of the invention.

### DETAILED DESCRIPTION OF THE INVENTION

Embodiments of the invention will now be described in detail with reference to the drawings.

In the present specification and drawings, the same elements as those described previously with reference to earlier figures are labeled with like reference numerals, and the detailed description thereof is omitted as appropriate.

### First Embodiment

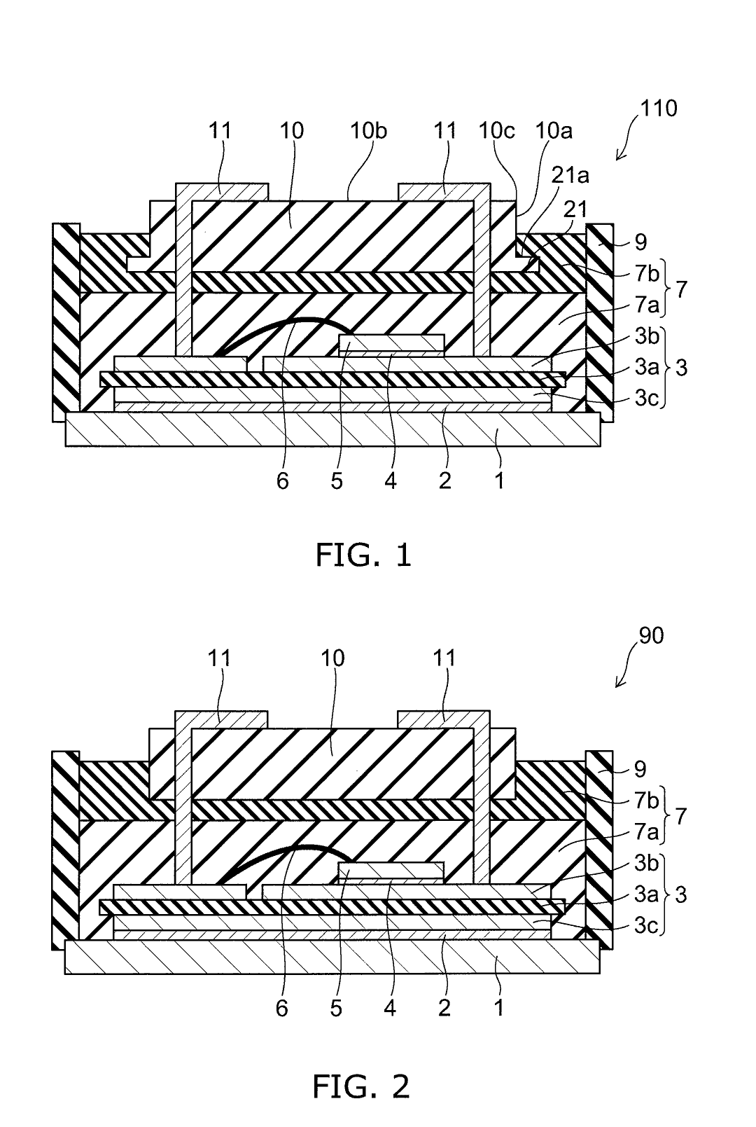

FIG. 1 is a schematic cross-sectional view illustrating the configuration of a semiconductor device according to a first embodiment of the invention.

As shown in FIG. 1, the semiconductor device 110 according to the first embodiment of the invention includes a base plate 1, a semiconductor element 5 provided on the base plate 1, a holder 10 provided on the opposite side of the semiconductor element from the base plate 1 and holding terminals 11 electrically connected to the semiconductor element 5, a casing 9 provided on the periphery of the base plate 1 and opposed to the side surface 10a of the holder 10, and a sealing resin 7 filled among the base plate 1, the casing 9, and the holder 10.

The side surface 10a of the holder 10 is provided with a first protrusion 21 which protrudes toward the casing 9. The first protrusion 21 is nearer to the base plate 1 than the major surface 10b of the holder 10 on the opposite side from the base plate 1. The surface 21a of the first protrusion 21 on the opposite side from the base plate 1 is at least partly buried in the sealing resin 7.

Hence, because the upper surface (surface 21a) of the first protrusion 21 of the holder 10 is covered with the sealing resin 7, no delamination fracture occurs between the holder 10 and the sealing resin 7 at the interface between the holder 10 and the sealing resin 7.

Thus, delamination at the interface between the holder 10 and the sealing resin 7 is prevented.

In the following, the semiconductor device 110 illustrated in FIG. 1 is described in detail.

As shown in FIG. 1, the semiconductor device 110 includes a base plate 1. The base plate 1 is illustratively made of a metal plate.

An insulating substrate 3 is provided on the base plate 1 via a solder 2. The insulating substrate 3 can illustratively include a ceramic plate 3a, a first circuit plate 3c provided on the base plate 1 side of the ceramic plate 3a, and a second circuit plate 3b provided on the opposite side of the ceramic plate 3a from the base plate 1. As illustrated in FIG. 1, the second circuit plate 3b is illustratively provided in a plurality.

A semiconductor element 5 is provided on the insulating substrate 3. The semiconductor element 5 is illustratively any of various power semiconductor elements such as a thyristor, diode, and transistor.

A wire 6 connected to one terminal of the semiconductor element 5, for example, is connected to one of the second circuit plates 3b, which is connected to one terminal 11. Another one of the second circuit plates 3b connected to the semiconductor element 5 is connected to another terminal 11. Although this figure shows two terminals 11, the number of terminals 11 is arbitrary.

The terminal 11 extends upward (away from the base plate 1) from the insulating substrate 3 and is held by the holder 10.

The side surface 10a of the holder 10 is provided with a first protrusion 21. The first protrusion 21 is nearer to the base plate 1 than the major surface 10b of the holder 10 on the opposite side from the base plate 1. The first protrusion 21 protrudes toward the casing 9.

The casing 9 is provided on the periphery of the base plate 1. The casing 9 is opposed to the side surface 10a of the holder 10.

Furthermore, a sealing resin 7 is provided among the base plate 1, the casing 9, and the holder 10. The upper surface and side surface of the insulating substrate 3, and the semiconductor element 5 are buried in the sealing resin 7.

The sealing resin 7 can illustratively include a first sealing resin 7a on the base plate 1 side and a second sealing resin 7b provided thereon. The first sealing resin 7a can be made of a silicone-based resin, which is highly insulative and chemically stable. The second sealing resin 7b can be made of an epoxy-based resin, which has high mechanical strength and moisture-proofness.

The semiconductor device 110 having the configuration as described above can be fabricated illustratively by placing the insulating substrate 3, the semiconductor element 5, the casing 9, and the holder 10 on the base plate 1 and then filling the sealing resin 7 (first sealing resin 7a and second sealing resin 7b) thereon.

In the semiconductor device 110 according to this embodiment, the side surface 10a of the holder 10 is provided with a first protrusion 21, and the surface 21a of the first protrusion 21 on the opposite side from the base plate 1 is covered with the sealing resin 7. Specifically, it is covered with the second sealing resin 7b having high mechanical strength. Hence, the protrusion 21 is caught by the sealing resin 7, avoiding delamination at the interface between the holder 10 and the base plate 1 even if a tensile force is applied between the holder 10 and the base plate 1.

Thus, delamination at the interface between the holder 10 and the sealing resin 7 is prevented.

### COMPARATIVE EXAMPLE

FIG. 2 is a schematic cross-sectional view illustrating the configuration of a semiconductor device of a comparative example.

As shown in FIG. 2, the semiconductor device 90 of the comparative example has no protrusion on the holder 10. The rest of the configuration is the same as that of the semiconductor device 110 according to this embodiment, and hence the description thereof is omitted.

In the semiconductor device 90 having such configuration, application of a tensile stress to the terminal 11 results in application of stress to the holder 10 holding the terminal 11, which causes shear delamination at the interface between the holder 10 and the sealing resin 7 (specifically, the second sealing resin 7b).

More specifically, in tensile limit tests for the base plate 1 and the terminal 11, fracture occurred at one of the interface between the holder 10 and the sealing resin 7 and the interface between the casing 9 and the sealing resin 7. The shear delamination strength was low with large variation.

In the semiconductor device 90 of the comparative example, creep-up of the first sealing resin 7a may deteriorate adhesion between the holder 10 and the other members, which significantly decreases the shear delamination strength. Variation in the amount of creep-up results in increasing the variation in the shear delamination strength.

In contrast, in the semiconductor device 110 according to this embodiment, in tensile limit tests for the base plate 1 and the terminal 11, no fracture occurs at the interface between the holder 10 and the sealing resin 7, but fractures, if any, occur at the interface between the casing 9 and the sealing resin 7, or in the casing 9. In general, the fracture strength is higher at the interface between the casing 9 and the sealing resin 7 than at the interface between the holder 10 and the sealing resin 7, and the casing 9 also has high fracture strength.

Furthermore, in the semiconductor device 110 according to this embodiment, the creep-up prevention effect of the first protrusion 21 prevents the creep-up of the first sealing resin 7a, which otherwise deteriorates adhesion. Hence, the shear delamination strength, and its variation due to the creep-up of the first sealing resin 7a, are improved.

Hence, in the semiconductor device 110 according to this embodiment, as compared with the comparative example, fracture sites are limited, and variation in the shear delamination strength is reduced. The shear delamination strength is improved to a practically sufficient level by preventing fractures at the interface between the holder 10 and the sealing resin 7.

Thus, the semiconductor device 110 according to this embodiment can provide a semiconductor device in which delamination at the interface between the holder and the sealing resin is prevented.

In the case where the sealing resin 7 includes a first sealing resin 7a on the base plate 1 side and a second sealing resin 7b provided thereon, the surface 21a of the first protrusion 21 on the opposite side from the base plate 1 is at least partly buried in the second sealing resin 7b, that is, the resin having higher mechanical strength and moisture-proofness.

On the other hand, as illustrated in FIG. 1, the semiconductor element 5 can be covered with the first sealing resin 7a. Thus, because the semiconductor element 5 is covered with the first sealing resin 7a, which has higher insulation and chemical stability than the second sealing resin 7b, the semiconductor element 5 can maintain good electrical characteristics, and the reliability of the semiconductor device 110 is improved.

On the other hand, in the technique disclosed in JP-A-11-238821, a ceiling plate for resin sealing is engaged with the upper end portion of a resin casing. However, because the ceiling plate is engaged with the resin casing, this technique requires high processing accuracy and complicates the manufacturing process, which remains to be a problem in practice.

### Second Embodiment

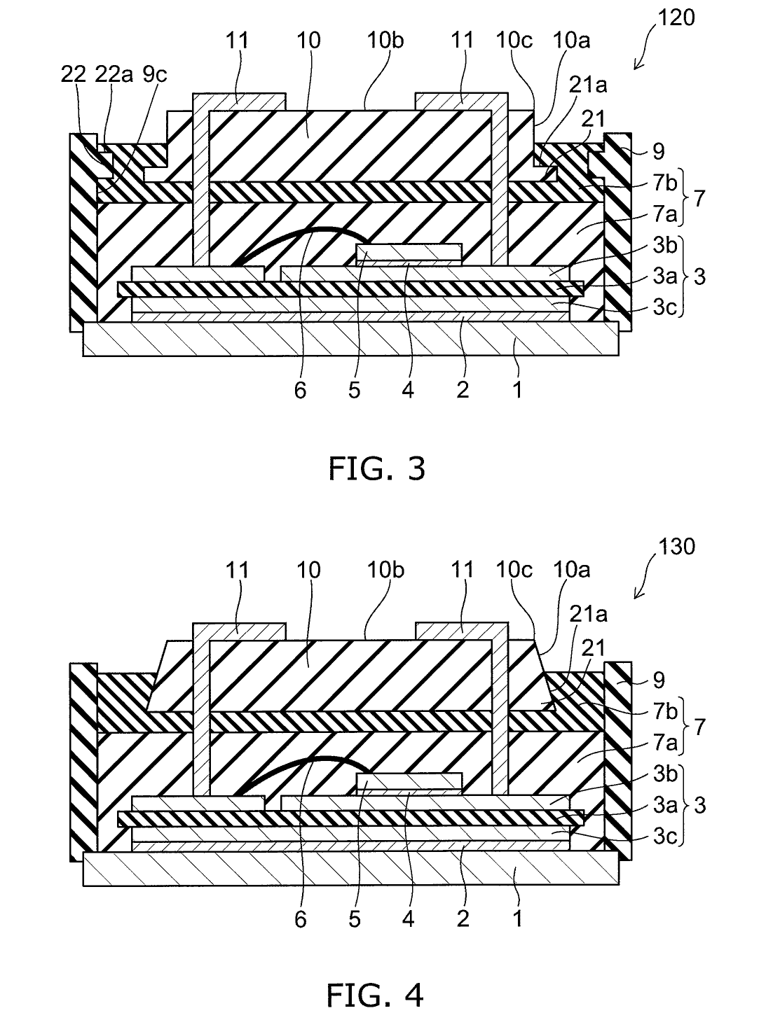

FIG. 3 is a schematic cross-sectional view illustrating the configuration of a semiconductor device according to a second embodiment of the invention.

As shown in FIG. 3, the semiconductor device 120 according to the second embodiment of the invention further includes a second protrusion 22 on the inner side surface of the casing 9 in the semiconductor device 110 according to the first embodiment. The rest of the configuration can be the same as that of the semiconductor device 110, and hence the description thereof is omitted.

More specifically, in the semiconductor device 120 according to this embodiment, the casing 9 has a second protrusion 22 provided on the surface 9c of the casing 9 opposed to the holder 10, and the surface 22a of the second protrusion 22 on the opposite side from the base plate 1 is at least partly buried in the sealing resin 7.

Thus, a semiconductor device having higher mechanical strength can be realized.

For example, in the semiconductor device 120 having such configuration, in tensile limit tests for the base plate 1 and the terminal 11, no fracture occurs at the interface between the holder 10 and the sealing resin 7 and the interface between the casing 9 and the sealing resin 7, but fractures, if any, occur only in the casing 9.

Thus, because fracture sites are limited to only the casing 9, variation in the fracture strength is reduced. Furthermore, although the tensile strength in the comparative example is the shear delamination strength between the components (holder 10, sealing resin 7, and casing 9), the tensile strength in the semiconductor device 120 according to this embodiment is the fracture strength of the casing 9 itself. Hence, the fracture strength can be twice or more as compared with the comparative example.

Furthermore, also in the semiconductor device 120 according to this embodiment, the creep-up prevention effect of the first protrusion 21 and the second protrusion 22 prevents the creep-up of the first sealing resin 7a, which otherwise deteriorates adhesion. Hence, the shear delamination strength, and its variation due to the creep-up of the first sealing resin 7a, are improved.

Thus, the semiconductor device 120 according to this embodiment can provide a semiconductor device in which delamination at the interface between the holder and the sealing resin and delamination at the interface between the casing and the sealing resin are prevented.

In the case where the sealing resin 7 includes a first sealing resin 7a on the base plate 1 side and a second sealing resin 7b provided thereon, the surface 22a of the second protrusion 22 on the opposite side from the base plate 1 is at least partly buried in the second sealing resin 7b, that is, the resin having higher mechanical strength and moisture-proofness.

### Third Embodiment

FIG. 4 is a schematic cross-sectional view illustrating the configuration of a semiconductor device according to a third embodiment of the invention.

As shown in FIG. 4, the semiconductor device 130 according to the third embodiment of the invention is different from the semiconductor device 110 according to the first embodiment in that the first protrusion 21 has a bevel. The rest of the configuration can be the same as that of the semiconductor device 110, and hence the description thereof is omitted.

In the semiconductor device 130 according to this embodiment, the first protrusion 21 has a bevel in which the distance between the holder 10 and the casing 9 is narrowed toward the base plate 1. That is, the first protrusion 21 is tapered.

Also in this embodiment, the side surface 10a of the holder 10 is provided with a first protrusion 21 which protrudes toward the casing 9. The first protrusion 21 is nearer to the base plate 1 than the major surface 10b of the holder 10 on the opposite side from the base plate 1. The surface 21a of the first protrusion 21 on the opposite side from the base plate 1 is at least partly buried in the sealing resin 7.

Thus, by a similar effect to that described in the first embodiment, delamination at the interface between the holder and the sealing resin can be prevented.

### Fourth Embodiment

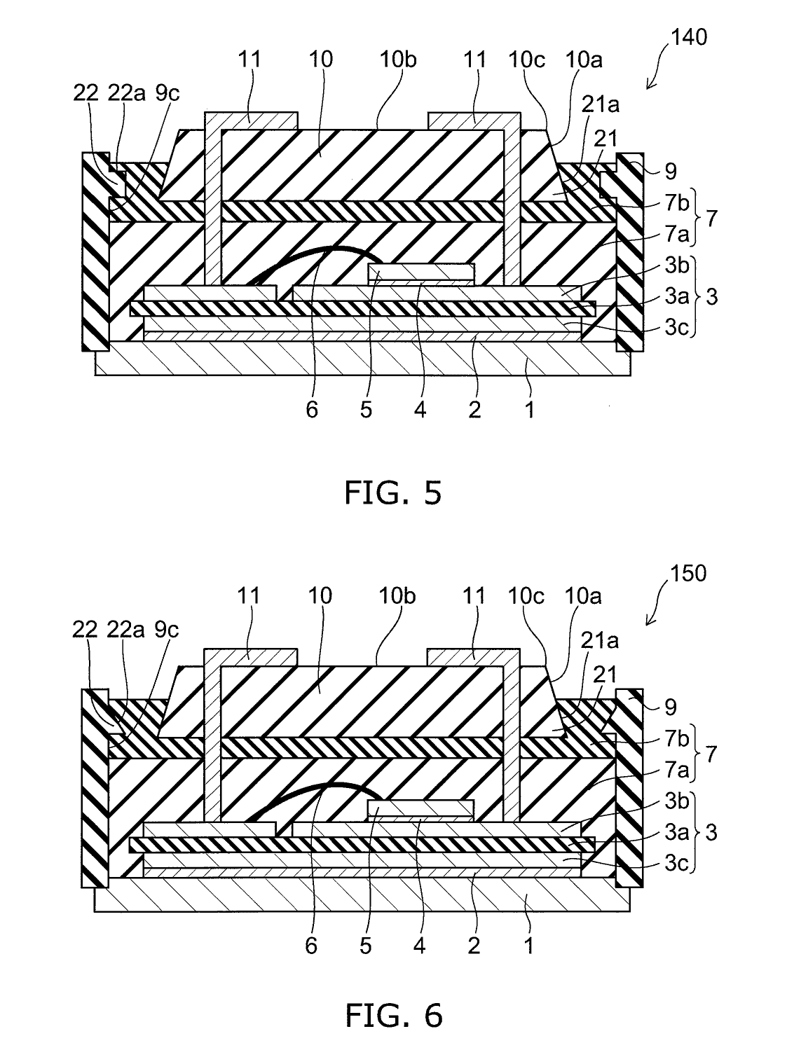

FIG. 5 is a schematic cross-sectional view illustrating the configuration of a semiconductor device according to a fourth embodiment of the invention.

As shown in FIG. 5, the semiconductor device 140 according to the fourth embodiment of the invention further includes a second protrusion 22 on the inner side surface of the casing 9 in the semiconductor device 130 according to the third embodiment. The rest of the configuration can be the same as that of the semiconductor device 110, and hence the description thereof is omitted.

Thus, by a similar effect to that described in the second embodiment, delamination at the interface between the holder and the sealing resin and delamination at the interface between the casing and the sealing resin can be prevented.

### Fifth Embodiment

FIG. 6 is a schematic cross-sectional view illustrating the configuration of a semiconductor device according to a fifth embodiment of the invention.

As shown in FIG. 6, the semiconductor device 150 according to the fifth embodiment of the invention is different from the semiconductor device 140 according to the fourth embodiment in that the second protrusion 22 has a bevel. The rest of the configuration can be the same as that of the semiconductor device 140, and hence the description thereof is omitted.

In the semiconductor device 150 according to this embodiment, the second protrusion 22 has a bevel in which the distance between the holder 10 and the casing 9 is narrowed toward the base plate 1. That is, the second protrusion 22 is tapered.

Also in this embodiment, the casing 9 has a second protrusion 22 provided on the surface 9c of the casing 9 opposed to the holder 10, and the surface 22a of the second protrusion 22 on the opposite side from the base plate 1 is at least partly buried in the sealing resin 7.

Thus, delamination at the interface between the holder and the sealing resin and delamination at the interface between the casing and the sealing resin can be prevented.

In the semiconductor devices 110 to 150 according to the above embodiments, the first protrusion 21 and the second protrusion 22 can have various planar shapes.

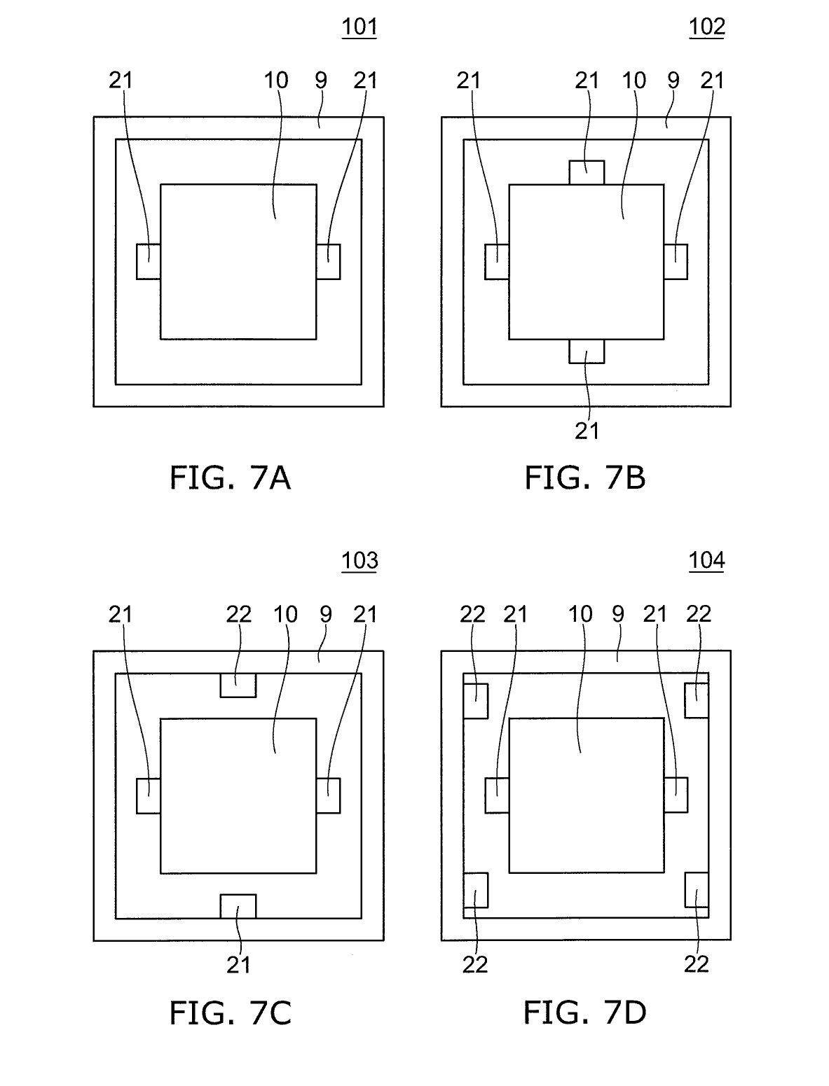

FIG. 7 is a schematic plan view illustrating configurations of the semiconductor device according to the embodiments of the invention.

This figure illustrates only the holder 10, the casing 9, the first protrusion 21, and the second protrusion 22, showing plan views as viewed in the direction perpendicular to the major surface of the base plate 1.

As shown in FIG. 7A, in the semiconductor device 101, the first protrusion 21 is provided on two opposed sides (side surfaces) of the holder 10. In FIG. 7A, each side surface is provided with one first protrusion 21. Alternatively, each side surface may be provided with a plurality of first protrusions 21.

As shown in FIG. 7B, in the semiconductor device 102, the first protrusion 21 is provided on four sides (side surfaces) of the holder 10. In FIG. 7B, each side surface is provided with one first protrusion 21. Alternatively, each side surface may be provided with a plurality of first protrusions 21.

As shown in FIG. 7C, in the semiconductor device 103, the first protrusion 21 is provided on two opposed sides (side surfaces) of the holder 10. Furthermore, the second protrusion 22 is provided on two opposed side surfaces of the casing 9 to which the first protrusion 21 is not opposed. In FIG. 7C, each side surface is provided with one first protrusion 21 or one second protrusion 22. Alternatively, each side surface may be provided with a plurality of first protrusions 21 or second protrusions 22.

As shown in FIG. 7D, in the semiconductor device 104, the first protrusion 21 is provided on two opposed sides (side surfaces) of the holder 10. Furthermore, the second protrusion 22 is provided on two opposed side surfaces of the casing 9 to which the first protrusion 21 is opposed. In this example, the first protrusion 21 is provided at the center portion of the side (side surface) of the holder 10. The second protrusion 22 is provided at the end portion of the side surface of the casing 9, two for each side surface. Thus, the surface of the casing 9 opposed to the holder 10 can include a plurality of flat surfaces, and the second protrusion 22 can be provided in a plurality on at least one of the plurality of flat surfaces. Here, the number of first protrusions 21 and second protrusions 22 on each side surface is arbitrary.

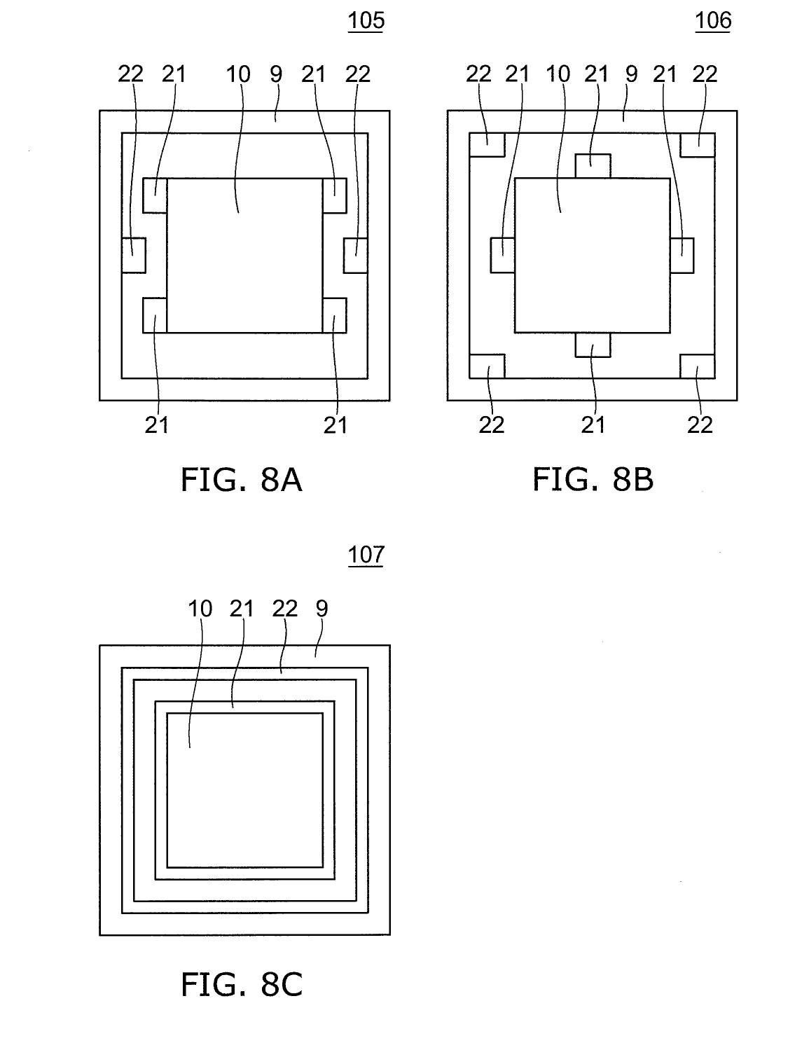

FIG. 8 is a schematic plan view illustrating other configurations of the semiconductor device according to the embodiments of the invention.

As shown in FIG. 8A, in the semiconductor device 105, the first protrusion 21 is provided at the end portion of two opposed sides (side surfaces) of the holder 10, two for each side surface. Thus, the side surface of the holder 10 can include a plurality of flat surfaces, and the first protrusion 21 can be provided in a plurality on at least one of the plurality of the flat surfaces. Furthermore, the second protrusion 22 is provided at the center portion of two opposed side surfaces of the casing 9 to which the first protrusion 21 is opposed. Also in this case, the number of first protrusions 21 and second protrusions 22 on each side surface is arbitrary.

As shown in FIG. 8B, in the semiconductor device 106, the first protrusion 21 is provided at the center portion of four sides (side surfaces) of the holder 10, one for each side surface. Furthermore, the second protrusion 22 is provided at the corner portion of the casing 9, one for each corner portion. Also in this case, the number of first protrusions 21 and second protrusions 22 on each side surface is arbitrary.

As shown in FIG. 8C, in the semiconductor device 107, the first protrusion 21 is provided so as to extend around the sides (side surfaces) of the holder 10. Furthermore, the second protrusion 22 is also provided so as to extend on the inner side surfaces of the casing 9.

The planar shapes of the above semiconductor devices 101 to 107 are applicable to each of the above semiconductor devices 110, 120, 130, 140, and 150.

In the example illustrated in FIG. 8C, the first protrusion 21 and the second protrusion 22 are opposed to each other in plan view. In this case, for a short distance between the holder 10 and the casing 9, the amount of sealing resin filled therebetween may locally decrease and result in decreased mechanical strength. Furthermore, it is difficult to fill the sealing resin without leaving voids.

Hence, in the case where the distance between the holder 10 and the casing 9 is relatively short, the first protrusion 21 and the second protrusion 22 can be provided so that they are not opposed to each other in plan view as illustrated in FIGS. 7C, 7D, 8A, and 8B. Thus, the decrease of mechanical strength and voids in the sealing resin can be avoided.

That is, the second protrusion 22 can be provided at a portion of the casing 9 which is not opposed to the first protrusion 21 in plan view in the direction perpendicular to the major surface of the base plate 1.

The embodiments of the invention have been described with reference to examples. However, the invention is not limited to these examples. For instance, various specific configurations of the components constituting the semiconductor device are encompassed within the scope of the invention as long as those skilled in the art can similarly practice the invention and achieve similar effects by suitably selecting such configurations from conventionally known ones.

Furthermore, any two or more components of the examples can be combined with each other as long as technically feasible, and such combinations are also encompassed within the scope of the invention as long as they fall within the spirit of the invention.

Furthermore, those skilled in the art can suitably modify and implement the semiconductor device described above in the embodiments of the invention, and all the semiconductor devices thus modified are also encompassed within the scope of the invention as long as they fall within the spirit of the invention.

Furthermore, those skilled in the art can conceive various modifications and variations within the spirit of the invention, and it is understood that such modifications and variations are also encompassed within the scope of the invention.

1. A semiconductor device comprising:
a base plate;
a semiconductor element provided on the base plate;
a holder provided on an opposite side of the semiconductor element from the base plate and holding terminals electrically connected to the semiconductor element;
a casing surrounding the semiconductor element and opposed to a side surface of the holder; and
a sealing resin filled among the base plate, the casing, and the holder,
the side surface of the holder being provided with a first protrusion protruding toward the casing, the first protrusion being nearer to the base plate than a major surface of the holder on an opposite side from the base plate, and
a surface of the first protrusion on an opposite side from the base plate being at least partly buried in the sealing resin.

2. The device according to claim 1, wherein the first protrusion has a bevel in which the distance between the holder and the casing is narrowed toward the base plate.

3. The device according to claim 1, wherein
the casing includes a second protrusion provided on a surface of the casing opposed to the holder, and
a surface of the second protrusion on an opposite side from the base plate is at least partly buried in the sealing resin.

4. The device according to claim 3, wherein the second protrusion has a bevel in which a distance between the holder and the casing is narrowed toward the base plate.

5. The device according to claim 3, wherein the second protrusion is provided at a position not opposed to the first protrusion in plan view in a direction perpendicular to a major surface of the base plate.

6. The device according to claim 3, wherein
the sealing resin includes a first resin provided on the base plate side and a second resin provided on an opposite side of the first resin from the base plate side and having higher mechanical strength than the first resin, and
the surface of the second protrusion on the opposite side from the base plate is at least partly buried in the second resin.

7. The device according to claim 3, wherein the surface of the casing opposed to the holder includes a plurality of flat surfaces, and the second protrusion is provided in a plurality on at least one of the plurality of flat surfaces.

8. The device according to claim 3, wherein the second protrusion is provided so as to extend on an inner edge of the surface of the casing opposed to the holder.

9. The device according to claim 1, wherein the sealing resin includes a first resin provided on the base plate side and a second resin provided on an opposite side of the first resin from the base plate side and having higher mechanical strength than the first resin.

10. The device according to claim 9, wherein the first resin has higher insulation than the second resin.

11. The device according to claim 9, wherein the first resin is a silicone-based resin, and the second resin is an epoxy-based resin.

12. The device according to claim 9, wherein a surface of the first protrusion on an opposite side from the base plate is at least partly buried in the second resin.

13. The device according to claim 9, wherein the semiconductor element is covered with the first resin.

14. The device according to claim 1, wherein the semiconductor element is one of a power thyristor, a power diode, and a power transistor.

15. The device according to claim 1, further comprising:
an insulating substrate provided on the base plate,
the semiconductor element being placed on the insulating substrate.

16. The device according to claim 15, wherein the insulating substrate includes a substrate being insulative, a first circuit plate provided on the base plate side of the substrate, and a plurality of second circuit plates provided on an opposite side of the substrate from the base plate.

17. The device according to claim 16, wherein one electrode of the semiconductor element is electrically connected to one of the terminals via one of the second circuit plates, and another electrode of the semiconductor element is electrically connected to another one of the terminals via another one of the second circuit plates.

18. The device according to claim 16, wherein the base plate is made of a metal and electrically connected to the first circuit plate.

19. The device according to claim 1, wherein the side surface of the holder includes a plurality of flat surfaces, and the first protrusion is provided in a plurality on at least one of the plurality of the flat surfaces.

20. The device according to claim 1, wherein the first protrusion is provided so as to extend around the periphery of the side surface of the holder.
